(19) United States
(12) Patent Application Publication
(10) Pub. No.: US 2026/0229626 A1
(43) Pub. Date: Aug. 6, 2026

(54) BATTERY MONITORING FOR DETECTION OF THERMAL EVENTS

(71) Applicant: GM GLOBAL TECHNOLOGY OPERATIONS LLC, DETROIT, MI (US)

(72) Inventor: Jihyun Kim, Rochester Hills, MI (US)

(21) Appl. No.: 19/045,081

(22) Filed: Feb. 4, 2025

(51) Int. Cl. H01M 10/48; G01K 3/00; G01R 31/3835; G01R 31/396

(52) U.S. Cl. CPC H01M 10/486; G01K 3/005; G01R 31/3835; G01R 31/396; H01M 10/482; H01M 2220/20

(57) ABSTRACT

A system for detection of thermal events in a battery system includes a sensing circuit operably connected to the battery system, the battery system including a plurality of sets of battery cells, the sensing circuit including a plurality of resistors, each resistor of the plurality of resistors disposed proximate to a respective set of battery cells, where the plurality of resistors are connected in parallel to a conductor. The system also includes a detector electrically connected to the plurality of resistors by the conductor, the detector configured to detect an electrical signal from the sensing circuit, the electrical signal based on a resistance of each resistor, and a processor configured to receive a value of the electrical signal during operation of the battery system, and identify a thermal event based on the electrical signal, the thermal event causing a change in a resistance of at least one resistor.

### INTRODUCTION

The subject disclosure relates to batteries, and more specifically to battery monitoring for detection of thermal events.

Vehicles, including gasoline and diesel power vehicles, as well as electric and hybrid electric vehicles, feature battery storage for purposes such as powering electric motors, electronics and other vehicle subsystems. Battery system health monitoring is an important aspect of battery operation. Thermal events can cause battery systems to malfunction. It is desirable to provide methods and systems that provide for improved detection and addressing of undesirable thermal events.

### SUMMARY

In one exemplary embodiment, a system for detection of thermal events in a battery system includes a sensing circuit operably connected to the battery system, the battery system including a plurality of sets of battery cells, the sensing circuit including a plurality of resistors, each resistor of the plurality of resistors disposed proximate to a respective set of battery cells, where the plurality of resistors are connected in parallel to a conductor. The system also includes a detector electrically connected to the plurality of resistors by the conductor, the detector configured to detect an electrical signal from the sensing circuit, the electrical signal based on a resistance of each resistor, and a processor configured to receive a value of the electrical signal during operation of the battery system, and identify a thermal event based on the electrical signal, the thermal event causing a change in a resistance of at least one resistor.

In addition to one or more of the features described herein, the plurality of resistors are disposed on a deformable substrate.

In addition to one or more of the features described herein, the deformable substrate is configured to rest on a surface of each of the sets of battery cells.

In addition to one or more of the features described herein, the thermal event includes a set of battery cells exceeding a threshold temperature.

In addition to one or more of the features described herein, the change in the resistance of the at least one resistor is based on a disconnection of the at least one resistor due to the thermal event.

In addition to one or more of the features described herein, the system includes a reference resistor connected to the sensing circuit, the reference resistor having a fixed resistance at a given input voltage.

In addition to one or more of the features described herein, the electrical signal is an output voltage of the sensing circuit, and the processor is configured to detect the thermal event based on the output voltage being greater than a reference voltage.

In addition to one or more of the features described herein, the processor is configured to determine an origin of the thermal event based on the electrical signal.

In addition to one or more of the features described herein, the electrical signal is an output voltage of the sensing circuit, and the processor is configured to determine the origin by comparing the output voltage to a plurality of output voltage reference values, each output voltage reference value indicating a set of battery cells at which the thermal event initiates.

In another exemplary embodiment, a method of detecting thermal events in a battery system includes monitoring a sensing circuit operably connected to the battery system, the battery system including a plurality of sets of battery cells, the sensing circuit including a plurality of resistors, each resistor of the plurality of resistors disposed proximate to a respective set of battery cells, where the plurality of resistors are connected in parallel to a conductor. The method also includes receiving an electrical signal at a detector electrically connected to the plurality of resistors by the conductor, the electrical signal based on a resistance of each resistor, and identifying a thermal event based on the electrical signal, the thermal event causing a change in a resistance of at least one resistor.

In addition to one or more of the features described herein, the plurality of resistors are disposed on a deformable substrate.

In addition to one or more of the features described herein, the thermal event includes a set of battery cells exceeding a threshold temperature.

In addition to one or more of the features described herein, the change in the resistance of the at least one resistor is based on a disconnection of the at least one resistor due to the thermal event.

In addition to one or more of the features described herein, the electrical signal is an output voltage of the sensing circuit, and identifying the thermal event includes comparing the output voltage to a reference voltage to determine whether the output voltage matches the reference voltage.

In addition to one or more of the features described herein, identifying the thermal event includes, based on the output voltage not matching the reference voltage, determining an origin of the thermal event based on the output voltage.

In addition to one or more of the features described herein, determining the origin includes comparing the output voltage to a plurality of output voltage reference values, each output voltage reference value indicating a set of battery cells at which the thermal event initiates.

In yet another exemplary embodiment a vehicle system includes a memory having computer readable instructions, and a processing device for executing the computer readable instructions, the computer readable instructions controlling the processing device to perform a method. The method includes monitoring a sensing circuit operably connected to a battery system, the battery system including a plurality of sets of battery cells, the sensing circuit including a plurality of resistors, each resistor of the plurality of resistors disposed proximate to a respective set of battery cells, where the plurality of resistors are connected in parallel to a conductor. The method also includes receiving an electrical signal at a detector electrically connected to the plurality of resistors by the conductor, the electrical signal based on a resistance of each resistor, and identifying a thermal event based on the electrical signal, the thermal event causing a change in a resistance of at least one resistor.

In addition to one or more of the features described herein, the electrical signal is an output voltage of the sensing circuit, and identifying the thermal event includes comparing the output voltage to a reference voltage to determine whether the output voltage matches the reference voltage.

In addition to one or more of the features described herein, identifying the thermal event includes, based on the output voltage not matching the reference voltage, determining an origin of the thermal event based on the output voltage.

In addition to one or more of the features described herein, determining the origin includes comparing the output voltage to a plurality of output voltage reference values, each output voltage reference value indicating a set of battery cells at which the thermal event initiates.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a top view of a motor vehicle including a battery system, in accordance with an exemplary embodiment;

FIG. 2 depicts a thermal event detection system, in accordance with an exemplary embodiment;

FIG. 3 is a circuit diagram depicting a sensing circuit, in accordance with an exemplary embodiment;

FIG. 4 is a flow diagram depicting aspects of a method of detecting thermal events, in accordance with an exemplary embodiment;

FIG. 5 is a circuit diagram depicting a portion of a sensing circuit and aspects of an example of a thermal event; and

FIG. 6 depicts a computer system in accordance with an exemplary embodiment.

### DETAILED DESCRIPTION

Devices, systems and methods are provided for monitoring a battery system and detecting thermal events. An embodiment of a thermal event detection system includes a sensing circuit having a plurality of resistors connected in parallel to each other and to a detector. Each resistor is disposed proximate to a respective set of cells in a battery system (e.g., an individual battery cell, a cell group, a battery module, etc.), such that a thermal event at the respective set of cells can displace the resistor or cause the resistor to disconnect from the sensing circuit, thereby changing a resistance of the sensing circuit.

The detection system is configured to monitor the battery system and the sensing circuit during operation, and detect or identify a thermal event, which includes an event or condition in which one or more sets of cells reaches a temperature that is above a threshold temperature. The thermal event may be identified or detected by comparing an electrical output of the sensing circuit to a reference value. The electrical output may also be used to find an origin of the thermal event.

For example, the detection system compares an output voltage to a reference output voltage and determines that a thermal event has occurred if the output voltage does not match the reference voltage. If a thermal event is detected, the detection system may compare the output voltage to reference data to identify which set of cells is the origin of the thermal event.

Embodiments described herein present numerous advantages and technical effects. The embodiments provide for effective detection and diagnosis of thermal events. The embodiments also provide for effective thermal event detection that is more efficient and requires fewer components than existing systems.

Existing battery management systems can find it challenging to accurately detect and track the origin of thermal events in battery cells. These systems typically rely on complex circuit compositions and multiple sensing channels, which can lead to increased noise. Embodiments address such limitations by providing a streamlined and efficient method to detect thermal events, which uses fewer components than existing systems.

For example, embodiments allow for replacing external sensors such as gas, pressure, or ambient temperature sensors with less complex and less resource-intensive designs using resistors (e.g., surface mounted (SMD) chip resistors). In addition, embodiments significantly improve detection time by configuring resistors to be directly impacted by gases produced by a thermal event.

Embodiments also provide effective means to define which specific cell or group of cells initially experiences a thermal event (i.e., which cell or group of cells is an origin of the event). This specific spot information can provide more deep-dive investigation opportunities, for example, by tracking a cell serial number or any structural or thermal management defect if there are multiple cells or sets of cells subject to a thermal event.

The embodiments are not limited to use with any specific vehicle and may be applicable to various contexts. For example, embodiments may be used with automobiles, trucks, aircraft, construction equipment, farm equipment, automated factory equipment and/or any other device or system that utilizes rechargeable energy storage systems.

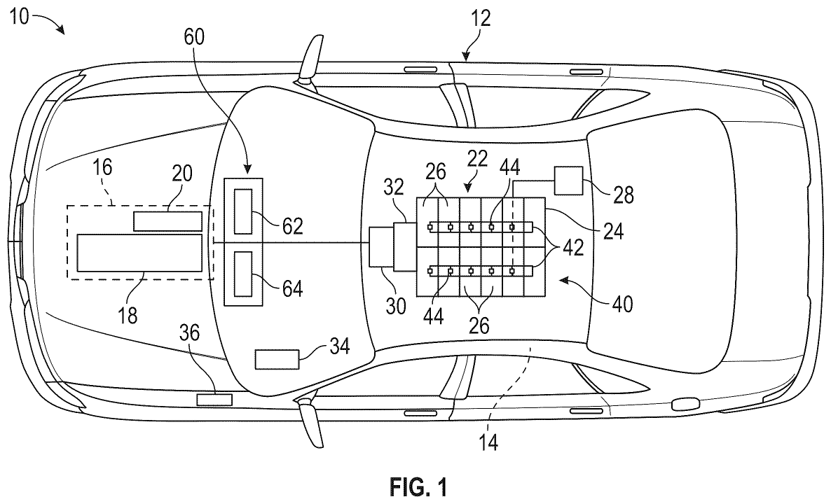

FIG. 1 shows an embodiment of a motor vehicle 10, which includes a vehicle body 12 defining, at least in part, an occupant compartment 14. The vehicle body 12 also supports various vehicle subsystems including a propulsion system 16, and other subsystems to support functions of the propulsion system 16 and other vehicle components, such as a braking subsystem, a suspension system, a steering subsystem, a fuel injection subsystem, an exhaust subsystem and others.

The vehicle 10 may be a combustion engine vehicle, an electrically powered vehicle (EV) or a hybrid vehicle. In an embodiment, the vehicle 10 is a hybrid vehicle that includes a combustion engine system 18 and at least one electric motor assembly. In an embodiment, the propulsion system 16 includes an electric motor 20, and may include one or more additional motors positioned at various locations. The vehicle 10 may be a fully electric vehicle having one or more electric motors.

The vehicle 10 includes a battery system 22, which may be electrically connected to the motor 20 and/or other components, such as vehicle electronics. The battery system 22 may be configured as a rechargeable energy storage system (RESS). In an embodiment, the battery system 22 includes a high voltage battery pack 24 having a plurality of battery modules 26.

The battery system 22 may also include a monitoring unit 28, such as a battery management system (BMS) controller, which includes components such as a processor, memory, an interface, a bus and/or other suitable components.

A “battery system,” in an embodiment, refers to a group of battery cells (i.e., two or more cells). For example, the battery system may be the battery pack 24, a battery module 26 or a group of cells in a module 26. In addition, a “battery module” may include a single cell or a group of cells forming a subset of the battery system, and is not limited to the specific configurations described herein.

The battery system 22 is electrically connected to components of the propulsion system 16. The propulsion system may also include an inverter module 30 and a DC-DC converter module 32. The inverter module 30 (e.g., a traction power inverter unit or TPIM) converts direct current (DC) power from the battery system 22 to poly-phase alternating current (AC) power (e.g., three-phase, six-phase, etc.) to drive the motor 20.

Various control modules (electronic control modules or ECUs) may be included in the vehicle 10. For example, an on-board charger module (OBCM) 34 may be included, which connects the battery system 22 to a charge port 36, and controls aspects of charging the battery system 22 (e.g., from a charging station, grid or other vehicle) and/or providing charge to an external system.

The battery system 22 includes or is connected to a thermal event detection system 40, which includes at least one sensing circuit 42. Each sensing circuit 42 includes a resistor 44 that is disposed proximate to a set of cells (i.e., one or more cells). In an embodiment, a resistor 44 is disposed proximate to one of the battery modules 26 (each resistor 44 is disposed proximate to a respective battery module 26). The detection system 40 is not so limited, as a resistor may be disposed proximate to a single cell, a cell group or any other set of cells.

The resistors 44 are connected in parallel to each other and to a processor such as the monitoring unit 28. Each resistor 44 is configured so that a thermal event, in which a component or components of the battery system 22 exceed(s) the temperature threshold, causes a change in a resistance of one or more resistors 44. The change in resistance may occur due to, for example, material expansion, air pressure increase and/or produced gases that impact a resistor and/or cause disconnection of the resistor 44 from the sensing circuit 40.

In an embodiment, the thermal event occurs when a temperature in a battery cell reaches the point that causes a chemical reaction to occur inside the battery cell. The reaction produces more heat that drives a fast temperature increase and can lead to malfunction. A thermal event in a cell or module may affect other cells and modules by causing temperature increases in adjacent cells or modules.

The vehicle 10 also includes a computer system 60 that includes one or more processing devices 62 and a user interface 64. The various processing devices and units may communicate with one another via a communication device or system, such as a controller area network (CAN) or transmission control protocol (TCP) bus. The computer system 60 may be configured to perform aspects of methods described herein, for example, in conjunction with the monitoring unit 28.

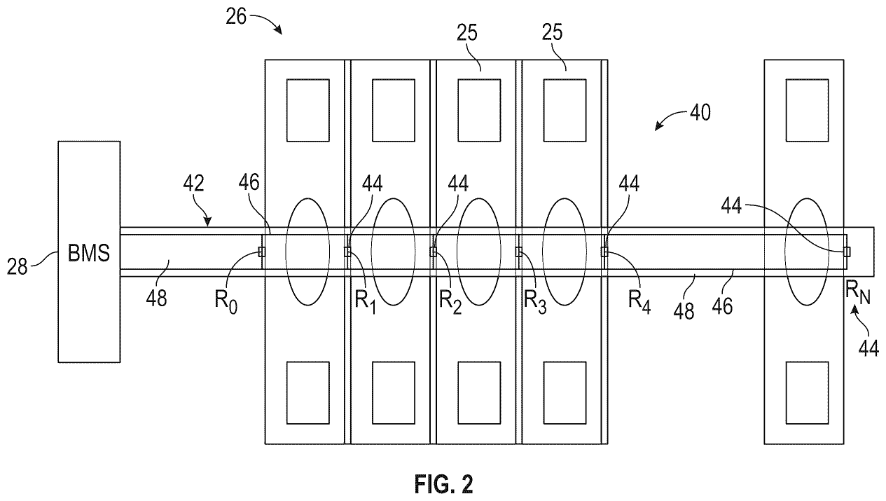

FIG. 2 depicts an embodiment of the thermal event detection system 40, as connected to an example of the battery module 26. In this example, the battery module 26 includes a series of cell groups 25. A number of resistors 44 are arrayed along the battery module 26, such that each resistor 44 (denoted as resistors R₀ through R_{N}) is directly above or otherwise proximate to a respective cell group 25.

It is noted that, although the sensing circuit 40 is configured to have a resistor 44 for each cell group 25, the sensing circuit 40 is not so limited. Each resistor 44 may be associated with any desired set (i.e., one or more) of cells. For example, a resistor 44 may be disposed relative to each battery module 26 (as shown in FIG. 1), or relative to each battery cell in a cell group, module or pack.

Each resistor 44 is disposed at a location proximate to a respective battery module (or other set of battery cells). As described herein, a resistor 44 is “proximate” to a battery cell or module, in that the resistor 44 is located such that a thermal event in the battery module directly and immediately impacts the resistor 44, causing a corresponding change in resistance of the resistor 44 or causing the resistor 44 to be disconnected from the sensing circuit 40 (e.g., by damaging the resistor 44).

The resistors 44 are connected in parallel to a conductor 46. The conductor 46 connects a sensing device, such as the monitoring unit 28, to the resistors 44. The detection system 40 thus avoids the need for dedicated sensing channels for each resistor 44 (e.g., a sensing channel for a high side and a low side of the resistors 44).

Each resistor is 44 positioned such that, when a cell group 25 (or other respective group of cells) experiences a thermal event of sufficient temperature (i.e., the temperature rises to a value that is at or above a threshold, and/or rises according to at least a selected rate), the resistor 44 is caused to be disconnected from the sensing circuit 40. This disconnection changes the overall resistance of the sensing circuit 40.

In an embodiment, the resistors 44 are disposed on a flexible or deformable substrate 48. The substrate 48 may be made from silicone, rubber or other suitable insulating material. This flexibility allows for the substrate 48 to maintain each resistor 44 at a fixed location relative to a respective set of cells, and allow each resistor 44 to be displaced or disconnected in response to a thermal event.

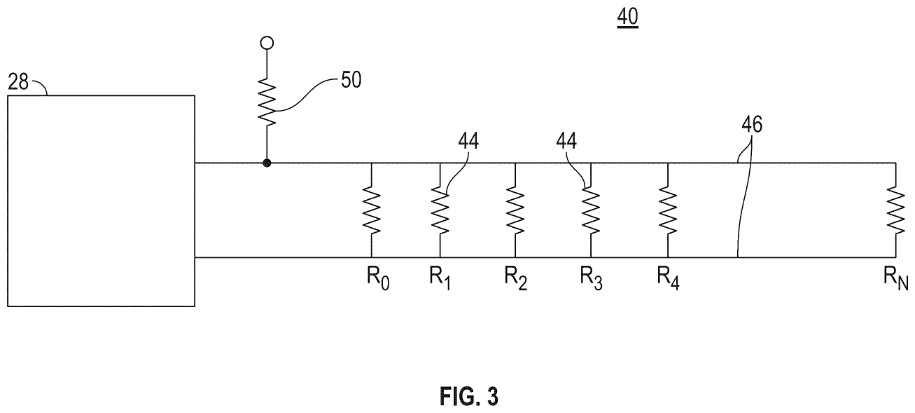

FIG. 3 is a circuit diagram that schematically depicts the sensing circuit 40. Each resistor R₀ through R_{N} has an initial resistance value.

A reference resistor 50, such as a pull-up resistor Rₚᵤₗₗ₋ᵤₚ, has a fixed resistance value, and is used to determine a reference value that is associated with normal operation. For example, a reference voltage associated with a given current is calculated based on the resistance of the reference resistor 50.

An output voltage V of the sensing circuit 40 is determined based on providing an input voltage, and determining an output voltage. The output voltage may be used as a reference voltage, which is a function of the resistances of the reference resistor 50 and the resistors 44. The output voltage V may be represented by the following equation, where N is a number of the resistors, and i is an index:

$$V = \frac{{( {\sum }_{\text{?}}^{\text{?}} \frac{1}{{R}_{\text{?}}} )}^{- \text{?}}}{( Rpull - up ) + {( {\sum }_{\text{?}}^{\text{?}} \frac{1}{{R}_{\text{?}}} )}^{- \text{?}}} .$$

$$\text{?} \text{indicates text missing or illegible when filed}$$

In an embodiment, the above equation is used to calculate a reference output voltage V_{ref}, which is correlated with normal operation. The reference output voltage V_{ref} is calculated using the above equation, an input voltage, and initial values of resistance for each resistor 44 and 50. For example, the input voltage is about 3 Volts (V) to about 5 V. The reference output voltage V_{ref} is tied to the fixed value of the reference resistor 50, and tied to the initial resistances of the resistors 44. It is noted that the input voltage, the reference voltage, and resistances of the various resistors are not limited to any specific examples described herein.

In an embodiment, the detection system 40 is configured to identify a thermal event by comparing a measured output voltage to the reference output voltage V_{ref}. A thermal event is identified, for example, if a measured output voltage exceeds the reference output voltage.

Based on identifying that a thermal event has occurred, the detection system 40 may further determine which set of cells originated the thermal event. In an embodiment a set of reference values is calculated for different thermal event scenarios (i.e., events that originated or started at different sets of cells). The measured output voltage may then be compared to the set of reference values to determine where the thermal event started.

Table 1 represents an example of a reference voltage, and an example of resistances of each resistor 44. The reference resistor 50 has a fixed resistance of 5000 Ohms at an input voltage of 3 Volts, and the resistances of each resistor 44 vary as shown:

TABLE 1
Reference Resistance Values for Reference Voltage of 3 V

| | | |
|---|---|---|
| Pull-up | 5000 | Ohms |
| R₀ | 50,000 | Ohms |
| R₁ | 30,000 | Ohms |
| R₂ | 20,000 | Ohms |
| R₃ | 10,000 | Ohms |
| R₄ | 5000 | Ohms |
| R₅ | 1000 | Ohms |

Table 2 represents an example of a normal or reference voltage (indicative of normal battery operation), and an example of various thermal event scenarios:

TABLE 2
Output Voltage

| | |
|---|---|
| Normal | 0.37 V |
| First Cell (R₀) Thermal Event | 2.73 V |
| Second Cell (R₁) Thermal Event | 2.37 V |
| Third Cell (R₂) Thermal Event | 1.98 V |
| Fourth Cell (R₃) Thermal Event | 1.49 V |
| Fifth Cell (R₄) Thermal Event | 0.99 V |

Each thermal event scenario represents a thermal event that originates at a different resistor 44. In the above example, a voltage value of 0.37 V represents normal operation (i.e., no thermal event is occurring). A voltage value that is above the reference value of 0.37 V (or greater than the reference value by a selected amount) is considered to be indicative of a thermal event.

For example, a value of 2.73 V indicates that a first cell group (proximate to the resistor R₀) is the origin of a thermal event. Table 2 also shows values associated with events originating at a second cell group (proximate to the resistor R₁), a third cell group (proximate to the resistor R₂), a fourth cell group (proximate to the resistor R₃), and a fifth cell group (proximate to the resistor R₄).

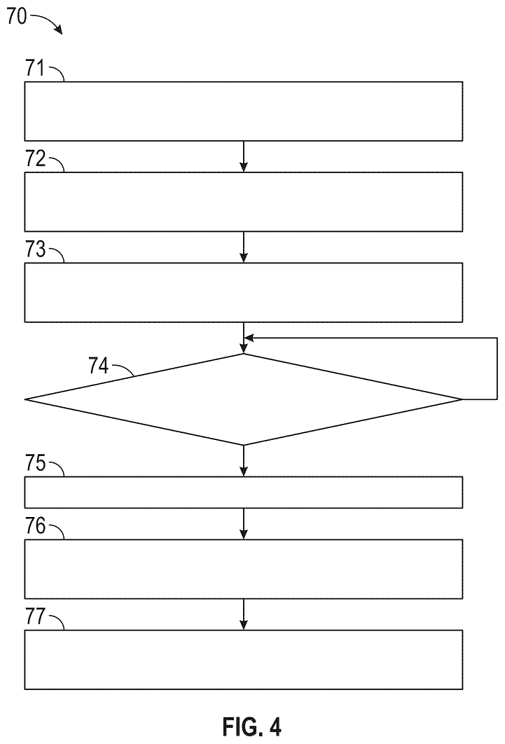

FIG. 4 illustrates embodiments of a method 70 of monitoring a battery system (e.g., the battery pack 24) and detecting thermal events (or other undesirable thermal events). Aspects of the method 70 may be performed by a processor or processors disposed in the vehicle 10 (e.g., the monitoring unit 28, the computer system 60, etc.). It is noted that the method 70 is not so limited and may be performed by any suitable processing device or system, or combination of processing devices.

The method 70 includes a number of steps or stages represented by blocks 71-77. The method 70 is not limited to the number or order of steps therein, as some steps represented by blocks 71-77 may be performed in a different order than that described below, or fewer than all of the steps may be performed.

At block 71, the detection system 40 determines an initial resistance value of each resistor, including the reference resistor 50 and the resistors 44. The initial resistance value may be determined based on pre-existing information, such as manufacturer specifications, or based on performing an initial resistance measurement.

At block 72, a set of resistance change values is generated or acquired. For example, a resistance change matrix is received or calculated, which indicates how the resistance changes in each resistor 44 when a given thermal event occurs.

At block 73, a reference value matrix or other data structure is generated that indicates output voltages for each of a plurality of different thermal events. For example, a reference output voltage is calculated for each of a plurality of thermal events, where each event initiates at a different cell group 25 (or other set of cells). An example of voltage reference values is shown in Table 2.

In addition, a reference output voltage associated with normal battery operation is determined. This value is referred to a normal voltage output value.

At block 74, the battery system 22 is monitored during vehicle operation or during other processes where the battery system 22 is being utilized (e.g., during charging of the battery system 22 or discharging to another device or system, such as vehicle-to vehicle or vehicle-to grid charging). An output voltage is measured continuously (e.g., at each sample time) or periodically. The measured output voltage is then compared to the normal voltage output value.

It is determined whether the measured output voltage value matches the normal voltage output value (i.e., is the same as the normal value or within a selected range of the normal value). If so, battery monitoring continues.

At block 75, if the measured output voltage does not match the normal voltage output value, a thermal event is detected. An alert or other indication that the event is detected may be provided to a vehicle system (e.g., an autonomous control system) or to a user or driver (e.g., via the user interface 64 of FIG. 1).

At block 76, upon detection of the thermal event, the monitoring unit 28 compares the measured output voltage to reference voltage values to determine where the thermal event originated. The monitoring unit 28 determines which output voltage reference value most closely matches the measured value.

At block 77, if the measured output voltage matches a reference voltage value, the monitoring unit 28 determines the specific cell group associated with the reference output voltage value, and outputs the cell or group number (or other identifying information).

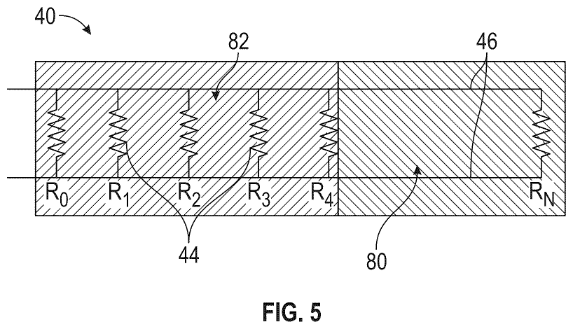

FIG. 5 shows an example of a thermal event. In this example, the thermal event initiated near the resistor R₄, causing a section 80 of the sensing circuit to be disconnected (e.g., due to heat melting the resistor and/or portions of the conductor 46). As a result, the section 80 of the circuit is open behind the resistor R₄. A section 82 of the circuit 42 between the resistor R₄ and the monitoring unit 28 (FIG. 3) now has a resistance that is different than the initial resistance of the circuit 40.

The monitoring unit 28 measures an output voltage of about 1.49 V, and compares the measured output voltage to a normal output voltage. In this example, the normal output voltage is 0.37 V and the resistors 44 have initial resistances shown in Table 1.

The monitoring unit 28 determines that a thermal event has occurred. The measured output voltage is then compared to reference voltage data, such as the data shown in Table 2. As a result, the monitoring unit 28 identifies the cell or cell group proximate to the resistor R₄ as the origin.

Based on detecting a thermal event, various actions may be taken. For example, the driver or a vehicle control system may shut off the vehicle (in conjunction with safely stopping the vehicle first, if applicable) or otherwise control vehicle or battery operation. In another example, diagnostic information may be provided to an external entity, such as a technician, fleet management system and/or dealership.

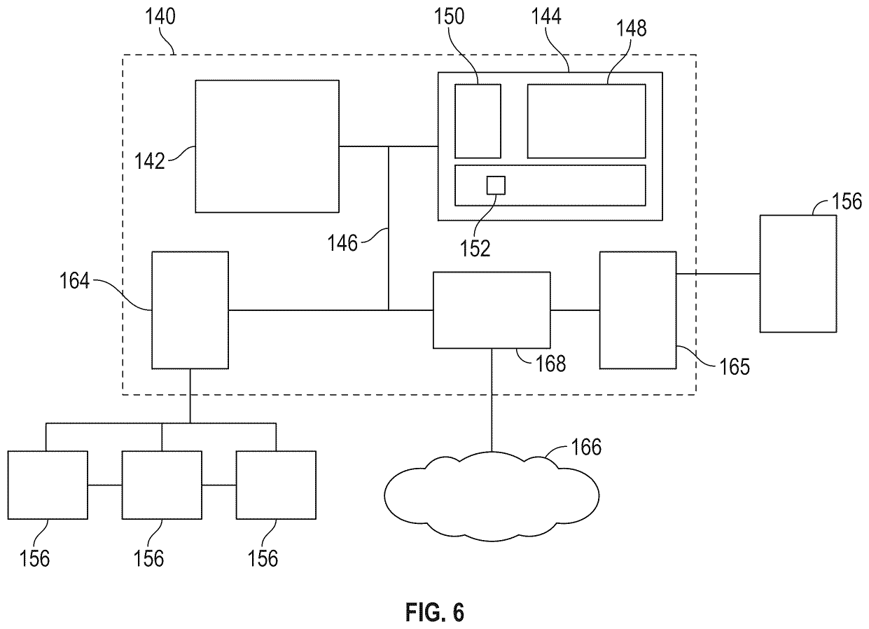

FIG. 6 illustrates aspects of an embodiment of a computer system 140 that can perform various aspects of embodiments described herein. The computer system 140 includes at least one processing device 142, which generally includes one or more processors for performing aspects of methods described herein.

Components of the computer system 140 include the processing device 142 (such as one or more processors or processing units), a memory 144, and a bus 146 that couples various system components including the system memory 144 to the processing device 142. The system memory 144 can be a non-transitory computer-readable medium, and may include a variety of computer system readable media. Such media can be any available media that is accessible by the processing device 142, and includes both volatile and non-volatile media, and removable and non-removable media.

For example, the system memory 144 includes a non-volatile memory 148 such as a hard drive, and may also include a volatile memory 150, such as random access memory (RAM) and/or cache memory. The computer system 140 can further include other removable/non-removable, volatile/non-volatile computer system storage media.

The system memory 144 can include at least one program product having a set (e.g., at least one) of program modules that are configured to carry out functions of the embodiments described herein. For example, the system memory 144 stores various program modules that generally carry out the functions and/or methodologies of embodiments described herein. A module or modules 152 may be included to perform functions related to battery monitoring and thermal event detection as discussed herein. The system 140 is not so limited, as other modules may be included. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

The processing device 142 can also communicate with one or more external devices 156 as a keyboard, a pointing device, and/or any devices (e.g., network card, modem, etc.) that enable the processing device 142 to communicate with one or more other computing devices. Communication with various devices can occur via Input/Output (I/O) interfaces 164 and 165.

The processing device 142 may also communicate with one or more networks 166 such as a local area network (LAN), a general wide area network (WAN), a bus network and/or a public network (e.g., the Internet) via a network adapter 168. It should be understood that although not shown, other hardware and/or software components may be used in conjunction with the computer system 140. Examples include, but are not limited to: microcode, device drivers, redundant processing units, external disk drive arrays, RAID systems, and data archival storage systems, etc.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A system for detection of thermal events in a battery system, comprising:
a sensing circuit operably connected to the battery system, the battery system including a plurality of sets of battery cells, the sensing circuit including a plurality of resistors, each resistor of the plurality of resistors disposed proximate to a respective set of battery cells, wherein the plurality of resistors are connected in parallel to a conductor;
a detector electrically connected to the plurality of resistors by the conductor, the detector configured to detect an electrical signal from the sensing circuit, the electrical signal based on a resistance of each resistor; and
a processor configured to receive a value of the electrical signal during operation of the battery system, and identify a thermal event based on the electrical signal, the thermal event causing a change in a resistance of at least one resistor.

2. The system of claim 1, wherein the plurality of resistors are disposed on a deformable substrate.

3. The system of claim 2, wherein the deformable substrate is configured to rest on a surface of each of the sets of battery cells.

4. The system of claim 1, wherein the thermal event includes a set of battery cells exceeding a threshold temperature.

5. The system of claim 1, wherein the change in the resistance of the at least one resistor is based on a disconnection of the at least one resistor due to the thermal event.

6. The system of claim 1, further comprising a reference resistor connected to the sensing circuit, the reference resistor having a fixed resistance at a given input voltage.

7. The system of claim 1, wherein the electrical signal is an output voltage of the sensing circuit, and the processor is configured to detect the thermal event based on the output voltage being greater than a reference voltage.

8. The system of claim 1, wherein the processor is configured to determine an origin of the thermal event based on the electrical signal.

9. The system of claim 8, wherein the electrical signal is an output voltage of the sensing circuit, and the processor is configured to determine the origin by comparing the output voltage to a plurality of output voltage reference values, each output voltage reference value indicating a set of battery cells at which the thermal event initiates.

10. A method of detecting thermal events in a battery system, comprising:
monitoring a sensing circuit operably connected to the battery system, the battery system including a plurality of sets of battery cells, the sensing circuit including a plurality of resistors, each resistor of the plurality of resistors disposed proximate to a respective set of battery cells, wherein the plurality of resistors are connected in parallel to a conductor;
receiving an electrical signal at a detector electrically connected to the plurality of resistors by the conductor, the electrical signal based on a resistance of each resistor; and
identifying a thermal event based on the electrical signal, the thermal event causing a change in a resistance of at least one resistor.

11. The method of claim 10, wherein the plurality of resistors are disposed on a deformable substrate.

12. The method of claim 10, wherein the thermal event includes a set of battery cells exceeding a threshold temperature.

13. The method of claim 10, wherein the change in the resistance of the at least one resistor is based on a disconnection of the at least one resistor due to the thermal event.

14. The method of claim 10, wherein the electrical signal is an output voltage of the sensing circuit, and identifying the thermal event includes comparing the output voltage to a reference voltage to determine whether the output voltage matches the reference voltage.

15. The method of claim 14, wherein identifying the thermal event includes, based on the output voltage not matching the reference voltage, determining an origin of the thermal event based on the output voltage.

16. The method of claim 15, wherein determining the origin includes comparing the output voltage to a plurality of output voltage reference values, each output voltage reference value indicating a set of battery cells at which the thermal event initiates.

17. A vehicle system comprising:
a memory having computer readable instructions; and
a processing device for executing the computer readable instructions, the computer readable instructions controlling the processing device to perform a method including:
monitoring a sensing circuit operably connected to a battery system, the battery system including a plurality of sets of battery cells, the sensing circuit including a plurality of resistors, each resistor of the plurality of resistors disposed proximate to a respective set of battery cells, wherein the plurality of resistors are connected in parallel to a conductor;
receiving an electrical signal at a detector electrically connected to the plurality of resistors by the conductor, the electrical signal based on a resistance of each resistor; and
identifying a thermal event based on the electrical signal, the thermal event causing a change in the resistance of at least one resistor.

18. The vehicle system of claim 17, wherein the electrical signal is an output voltage of the sensing circuit, and identifying the thermal event includes comparing the output voltage to a reference voltage to determine whether the output voltage matches the reference voltage.

19. The vehicle system of claim 18, wherein identifying the thermal event includes, based on the output voltage not matching the reference voltage, determining an origin of the thermal event based on the output voltage.

20. The vehicle system of claim 19, wherein determining the origin includes comparing the output voltage to a plurality of output voltage reference values, each output voltage reference value indicating a set of battery cells at which the thermal event initiates.
